(19) United States
(12) Patent Application Publication
(10) Pub. No.: US 2012/0091011 A1
(43) Pub. Date: Apr. 19, 2012

(54) BIOCOMPATIBLE ELECTRODE

(75) Inventors: Anthony H.D. Graham, Bath (GB); John Taylor, Bath (GB); Chris R. Bowen, Bath (GB); Jon Robbins, London (GB)

(73) Assignee: University of Bath Research and Innovations Services, Bath (GB)

(21) Appl. No.: 13/128,440

(22) PCT Filed: Nov. 10, 2009
(86) PCT No.: PCT/GB2009/002641

§ 371 Date: Dec. 22, 2011

(30) Foreign Application Priority Data
Nov. 11, 2008 (GB) 0820629.4

(51) Int. Cl. G01N 27/26; H01L 21/28; B01D 43/00; H01L 29/41

(52) U.S. Cl. 205/775; 257/751; 438/669; 204/450; 204/547; 257/E29.112; 257/E21.158

(57) ABSTRACT

A biocompatible electrode formed from an integrated circuit, the electrode comprising: a semiconductor substrate; and an electrode layer at least partially comprising porous valve metal oxide.

The present invention relates to a biocompatible electrode for use in applications such as electrophysiological applications, and a method of manufacturing thereof.

Various areas of biomedicine require the ability to stimulate and record from adherent cells such as neurons, cardiomyocytes, and some cell lines. Applications in these areas include drug discovery, pharmacology, cell-based biosensors and neural interface systems.

In the last few years a significant amount of growth in the drug discovery market has been due to growth in high throughput screening (HTS). This requires monitoring of the electrophysiological response of cells to compound libraries and is presently lacking a high volume solution to convey the required information relating to this electrophysiological response. A single assay used in HTS may contain many multi-well plates and each such plate may contain, for example, 384 wells. Therefore large quantities of electrodes are required to address all of the wells and so the cost and therefore ease of manufacture of individual electrodes is critical.

Biosensors other than for use in HTS have been developed during the past thirty years for applications such as medical health applications, environmental toxicology (e.g. detections of toxins such as organophosphates) and sensors in the defence against biological or chemical warfare. A complete biosensor requires ‘support’ electronics, i.e. ‘active’ components, which currently requires multiple chips to be used. Neural interface systems are now being developed in order to assist in the diagnosis, management and ultimately cure of nervous system disorders. Such systems also require connection with other necessary electronic components. These biosensor and neural interface applications are lacking a suitable electrode solution for allowing integration with other components.

Current attempts at producing suitable electrodes for electrophysiological applications have required custom fabrication and therefore have been complicated and high cost to manufacture, have not allowed the required level of miniaturisation and have been unreliable.

For example, there currently exist multi-electrode arrays (MEAs) for electrophysiological applications but these are limited, simple, passive devices which do not allow for integration with electronic circuits. These are also high cost/volume and therefore focussed on research and development applications.

There have been attempts at using existing integrated circuit (IC) technology to produce working electrodes for applications such as HTS, in order to attempt to enable integration with electronic circuits. However, these have had limited results. To produce the electrodes a completed IC must undergo complex post-processing to make the electrodes biocompatible and this also requires expensive microfabrication equipment and clean-room facilities. This is therefore not suitable for high volume, low cost applications.

In summary there is currently no available reliable, low cost, ‘active’ biocompatible electrode which is simple to manufacture on a large scale and is suitable for biosensors, implants and electrophysiological applications such as drug discovery assays.

The invention is set out in the claims.

The invention provides a reliable, non-corroding, biocompatible electrode, which can be integrated with other electronic components, by basing the electrode structure on an integrated circuit (IC) but vastly reducing risk of corrosion of the electrode layer to be exposed to, for example, a physiological medium, by means of the electrode layer comprising porous valve metal oxide.

Manufacture of the electrode is simple and therefore low cost and possible at high volumes, because the electrode can be manufactured using readily available, low-cost IC technology.

Examples of the invention will now be described with reference to the accompanying drawings, in which:

FIG. 1 is a diagram showing an example biocompatible electrode in accordance with the invention;

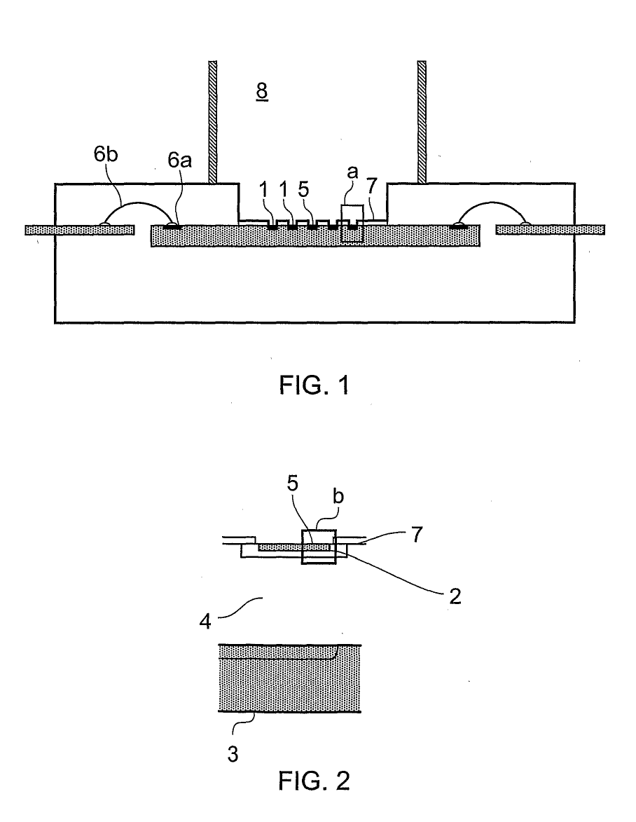

FIG. 2 is a an enlarged diagram showing the part of FIG. 1 marked with box a;

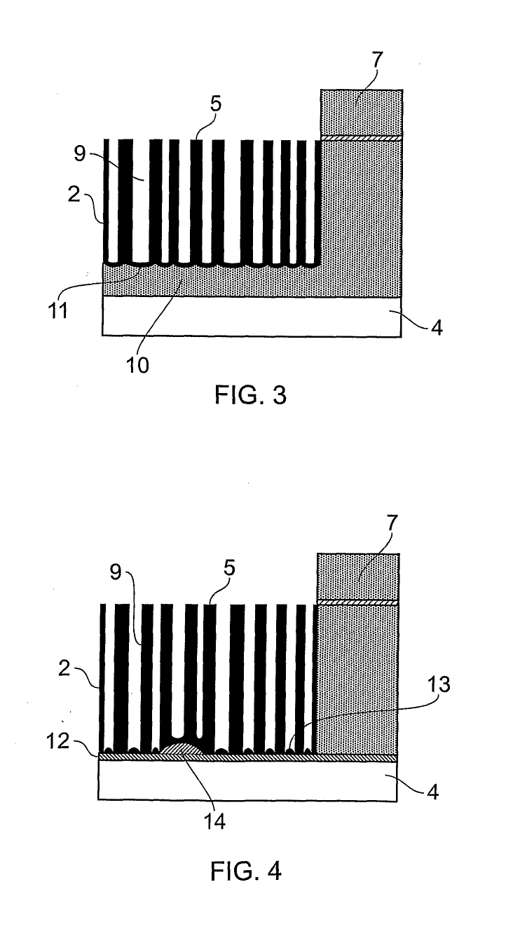

FIG. 3 is a diagram of an example partially completed electrode layer, corresponding to an enlarged diagram showing the part of FIG. 2 marked with box b (details of edge effects have been omitted for simplification and clarification);

FIG. 4 is a diagram showing an example electrode layer;

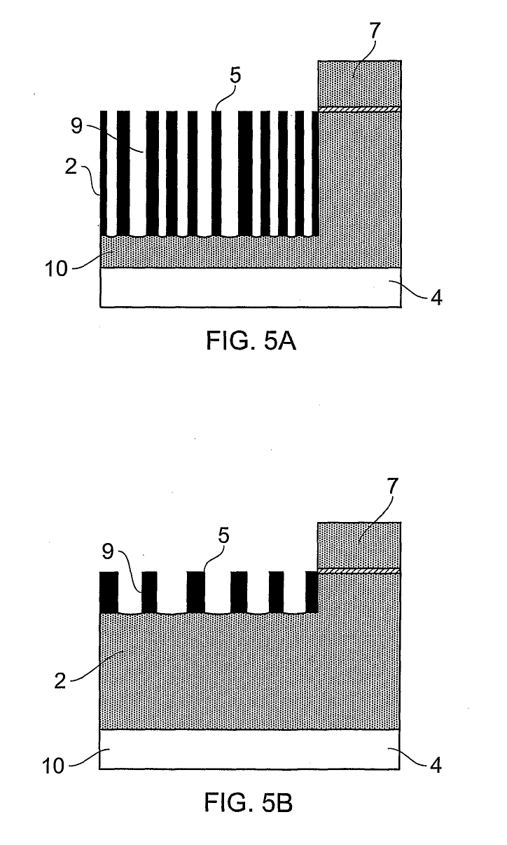

FIGS. 5A and 5b are diagrams showing example electrode layers having pores which have been widened and barrier oxide thinned with an etch;

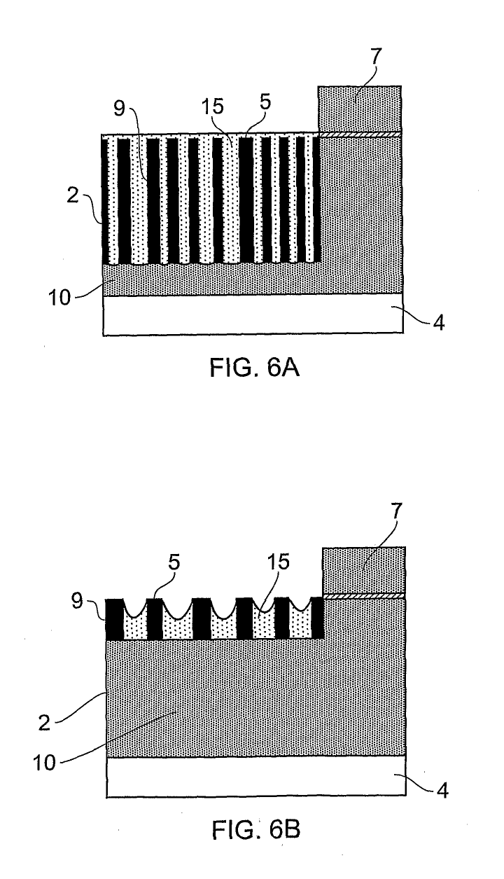

FIGS. 6A and 6B are diagrams showing example electrode layers having noble metal coatings;

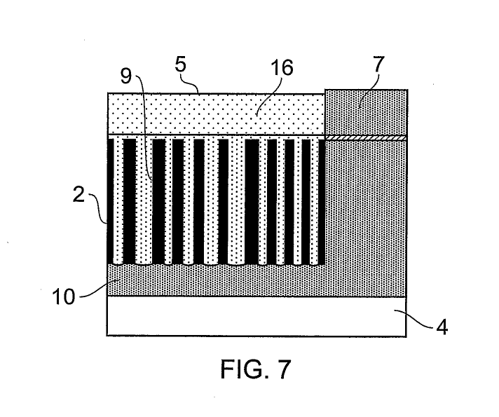

FIG. 7 is a diagram showing an example electrode layer having a noble metal coating and a further coating;

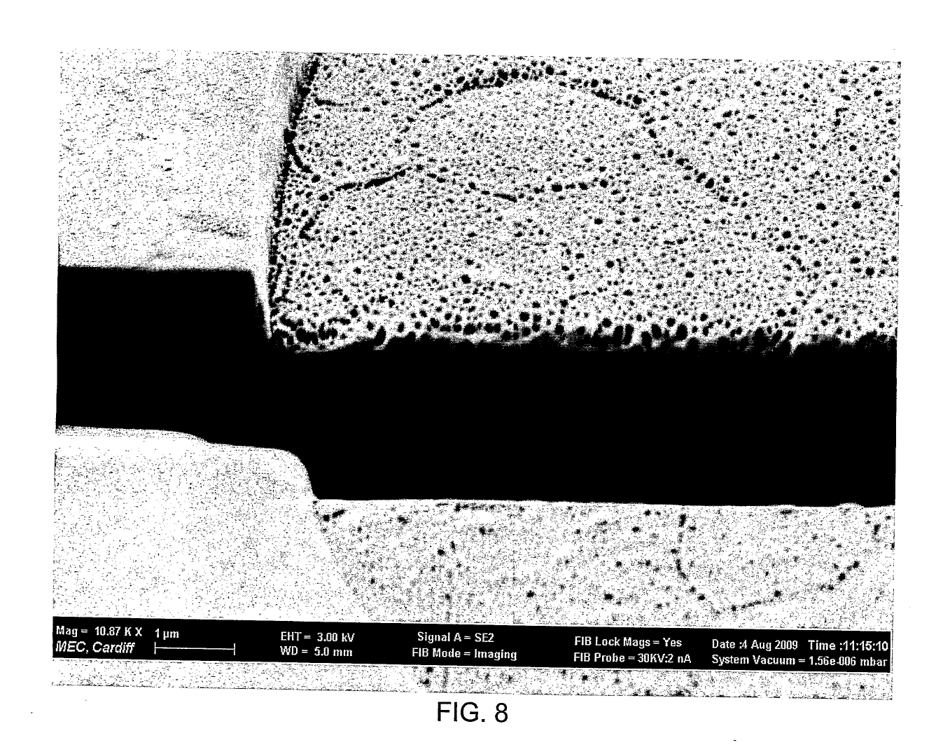

FIG. 8 is an image of a biocompatible electrode having an electrode layer as shown in FIG. 4;

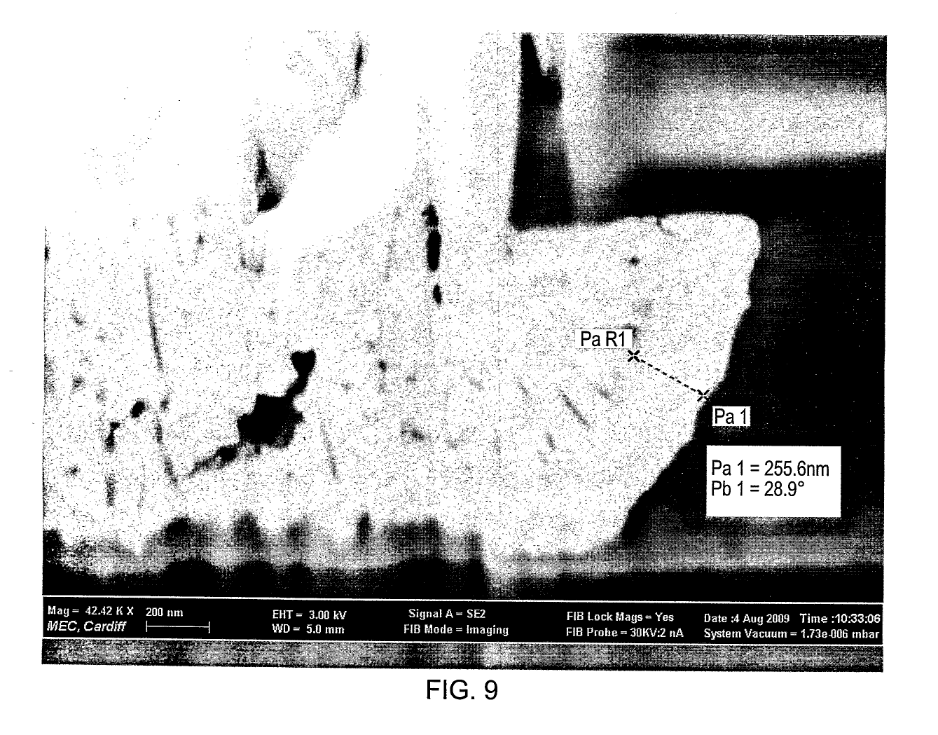

FIG. 9 is an image of a biocompatible electrode having an electrode layer as shown in FIG. 6A;

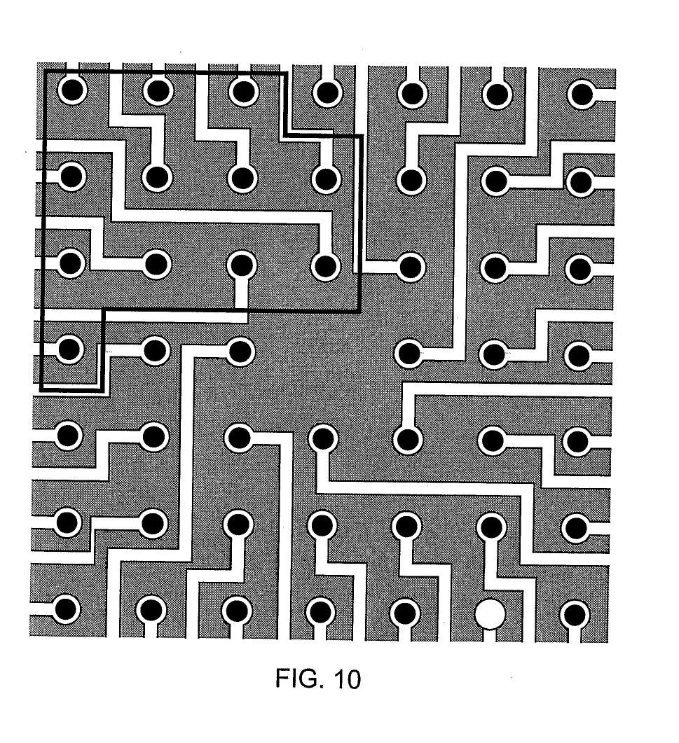

FIG. 10 is an image of a microelectrode array of electrodes having electrode layers as shown in FIG. 6A;

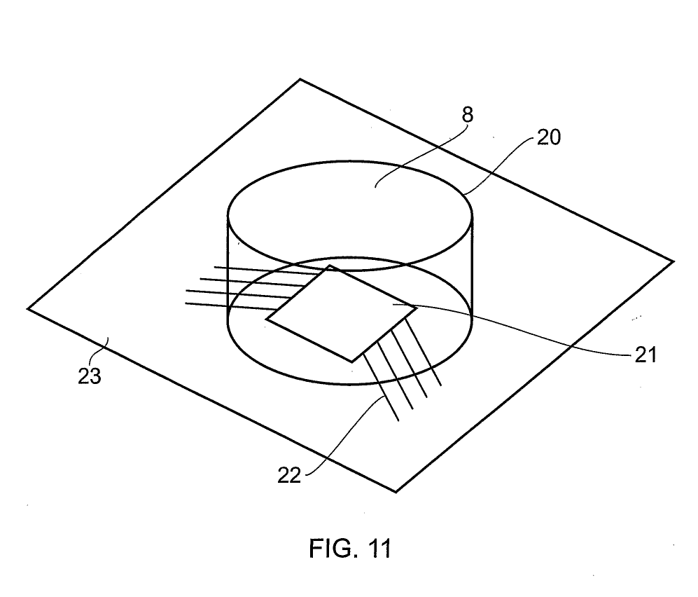

FIG. 11 is a schematic diagram of an example biosensor;

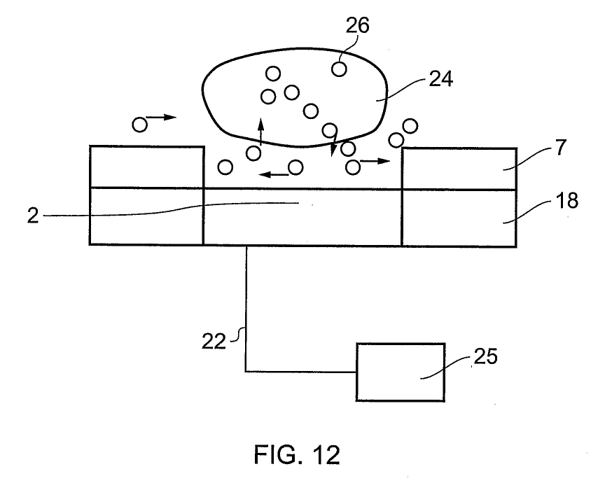

FIG. 12 is a diagram of how electrical recording/stimulation of cells may occur with an example electrode;

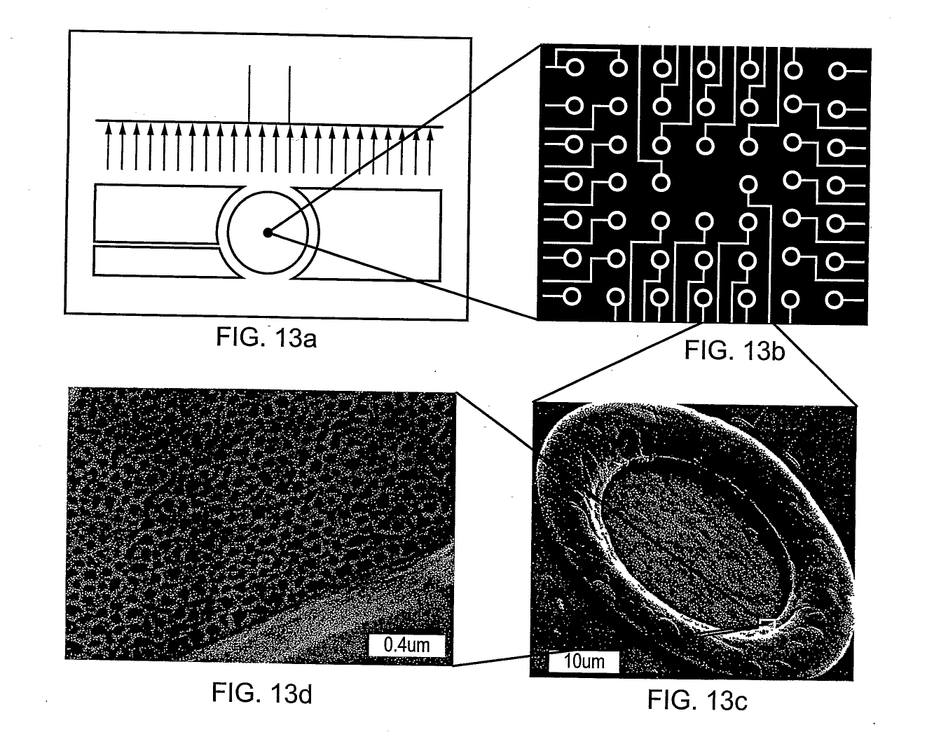

FIGS. 13a to 13d show schematic diagrams of an example biosensor and portions thereof;

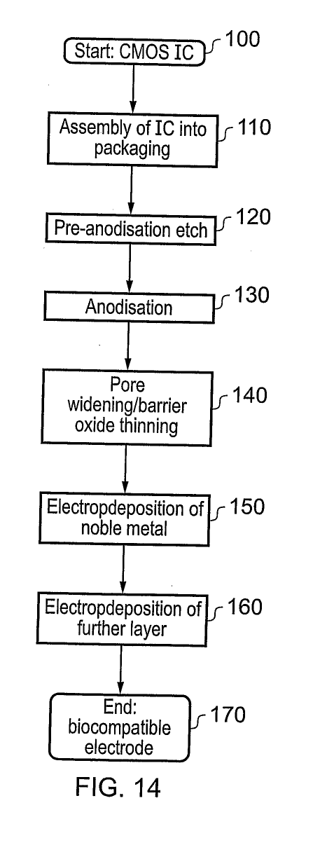

FIG. 14 is a flow diagram showing process steps of an example method of manufacturing a biocompatible electrode in accordance with the invention;

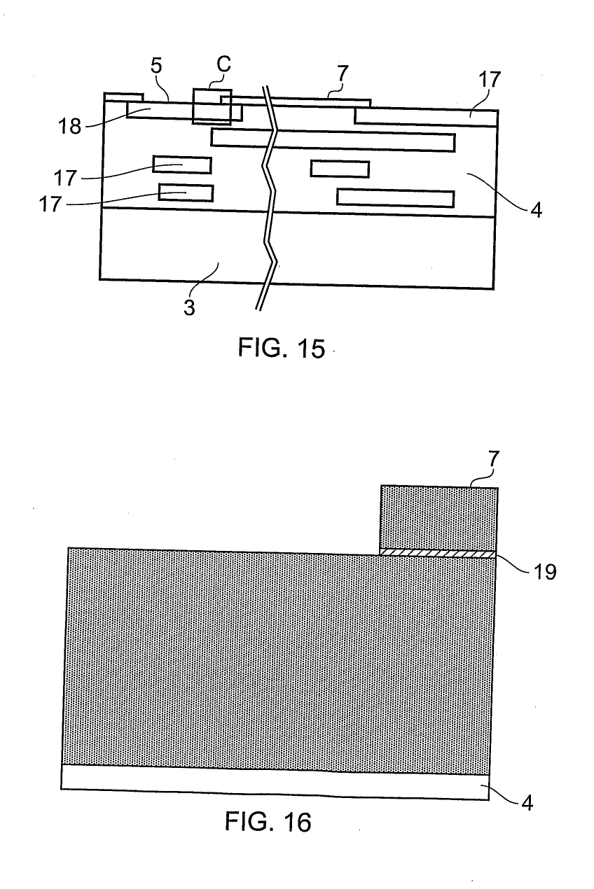

FIG. 15 is a diagram showing an example CMOS IC as the starting point of the process shown in FIG. 14;

FIG. 16 is an enlarged diagram showing the part of FIG. 15 marked with box c;

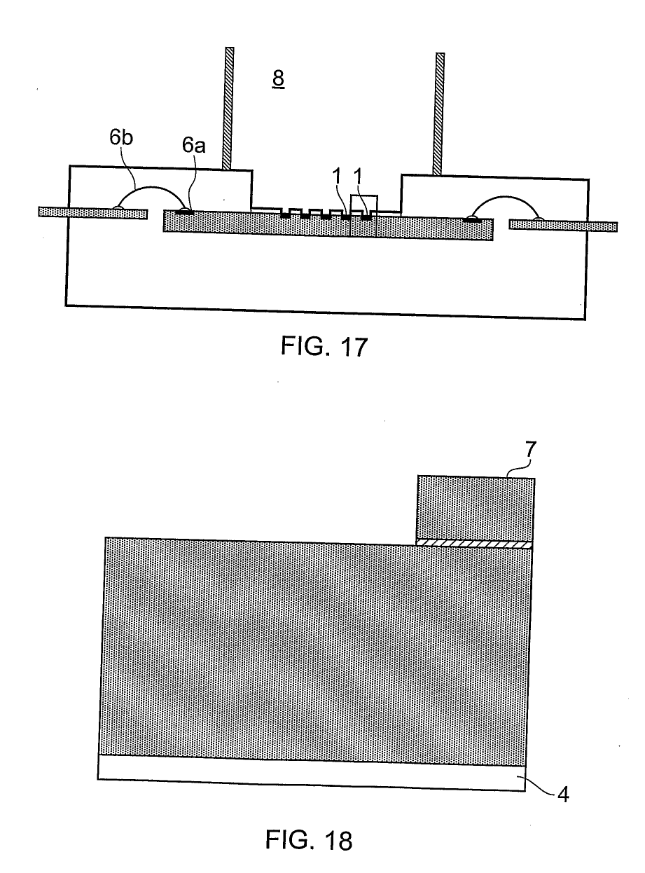

FIG. 17 is a diagram showing an IC package assembled so that electrode areas may be exposed to an electrolyte; and

FIG. 18 shows the view of FIG. 16 after a pre-anodisation etch has optionally occurred.

An example electrode package is shown in FIG. 1, having multiple electrodes 1. FIG. 2 shows an enlarged version of the box marked a in FIG. 1 giving detail of one electrode 1, and FIG. 3 shows an enlarged version of the box marked b in FIG. 2 giving further detail of the electrode layer 2 of an electrode 1 before provision has been made for electrical connection.

An example electrode 1 comprises a semiconductor substrate 3, an insulating dielectric layer 4 and an electrode layer 2. The electrode layer 2 has an exposed surface 5 arranged to come into contact, in use, with the relevant medium, for example a culture medium supporting cells being tested. The examples discussed herein also have an insulating layer 4 between the substrate 3 and the electrode layer 2, although the insulating layer 4 may be omitted and the electrode layer 2 may directly contact the substrate 3.

The electrode package shown in FIG. 1 is an open package to expose the surface 5 and to insulate bond pads 6a and bond wires 6b. There is a passivation layer 7 surrounding the exposed surface 5. The example shown in FIG. 1 has a culture chamber 8 arranged to hold a culture medium for in-vitro applications. As discussed below, the package and chamber 8 are optionally also used during the manufacturing process to hold electrolyte and etchant, which has the advantage of simplifying manufacturing.

The basic structure of an example partially completed electrode layer 2 is shown in detail in FIG. 3, before provision has been made for electrical connection. The electrode layer 2 comprises a porous alumina layer 9 formed from anodised aluminium as discussed in further detail below. Between the alumina layer 9 and the insulating layer 4 is a thinned aluminium layer 10 which may act as an electrical connection to/from the electrode 1 (electrical connections not shown). In this example there is also an alumina layer 11 at the base of each pore.

In the examples discussed herein, the porous layer is referred to as being alumina, although as an alternative other valve metal oxides may be used, as discussed below.

An example electrode layer 2 is shown in FIG. 4. In this example the electrode 1 further comprises a barrier layer 12 adjacent to the insulating layer 4 which may be, for example, titanium and/or titanium nitride. Further, the example of FIG. 4 has no aluminium present between the alumina layer 9 and the barrier layer 12 in some areas on the barrier layer 12, leaving only an alumina barrier layer 13, and in other areas only a very small amount 14 of aluminium remains.

In another example (not shown) no aluminium may remain, so that there are no small amounts 14 of aluminium and only an alumina barrier layer 13 present.

FIGS. 5A and 5B show example electrode layers 2 each in an electrode 1 having no barrier layer 12, a thinned aluminium layer 10, and no alumina barrier layer 13. The example shown in FIG. 5A has tall, narrow pores and FIG. 5B has short, wide pores.

Electrical connection (not shown) may be made in the above examples in any suitable manner using any remaining aluminium 10, 14 or barrier layer 12.

FIG. 6A shows an example as in FIG. 5A but also further comprising a noble metal coating 15 which fills the pores. Such a coating 15 firstly improves the conductivity of the electrode 1. Coating may be used to establish an electrical connection between the electrode surface 5 and the electrical connection from 10, 14, or 12. Any pores that would fail to conduct through a thick barrier oxide 11, 13 or lack of conducting aluminium 10 below may be connected electrically via the metal coating 15. Secondly, this prevents access of corrosive medium to any residual aluminium at the base of the pores.

The precise nature of the noble metal coating 15 may vary. An alternative option to the coating 15 which fills the pores, as shown in FIG. 6A, is a thin layer that follows the porous alumina topography, as shown in FIG. 6B, providing a high surface area based on the nature of the porous alumina, or a layer that partly fills each pore, thereby providing the benefits of the thin layer but also minimising the risk of corrosive medium penetrating to the layers underlying the alumina. An example of such a coating 15 is a ductile platinum layer.

FIG. 7 shows an example as in FIG. 6A but also further comprising a further coating 16, to further improve performance. This layer may be, for example, ‘Platinum Black’ (‘platinised platinum’).

A further example (not shown) is to use a metal coating 15 which mainly fills the pores, similarly to the example shown in FIG. 6A, but with the porous alumina not completely covered by the metal. The alumina is then partially etched back using acid electrolyte to leave a nano-textured surface of noble metal ‘rods’. This presents a high surface area of metal, giving low impedance, with structural support for the rod bases plus protection of any underlying aluminium from the remaining alumina walls.

The various features of the electrode layer 2 discussed in the above examples may be controlled and combined in many ways, depending on the desired structure of the resultant electrode 1, and are not limited to the examples shown in FIGS. 3 to 7. For example, any of the type of electrolyte, concentration of electrolyte and anodising voltage may be varied. Annealing may be used. Surface chemistry may be altered using, for example, chemical dips. Controlling the anodisation conditions, etching and coating are discussed below where the manufacturing process is described.

FIGS. 8 and 9 are images of completed biocompatible CMOS electrodes. FIG. 8 shows an electrode 1 having an electrode layer 2 as shown in FIG. 4. The electrode 1 has a thinned barrier oxide 13 at the base of each pore, giving an impedance similar to that of an unmodified, non-biocompatible aluminium pad. FIG. 9 shows an electrode 1 having an electrode layer 2 as shown in FIG. 6A. The porous alumina is filled with platinum 15, giving a lower impedance than an unmodified aluminium pad.

An image of an example microelectrode array comprising biocompatible electrodes 1 is shown FIG. 10. The array shown in FIG. 10 comprises electrodes 1 having electrode layers 2 as shown in FIG. 6A. Control pads are porous alumina with no plating (here with a pad diameter of 30 μm) and other pads have been platinum plated for 1 or 1.5 hours.

The above-described electrode 1 may be used in applications where a biocompatible electrode for recording or stimulation is required that does not corrode, for example, in a physiological medium. Further it may be used where integration with other electronic components is required and also where multiple electrodes are required. For example, the electrode 1 may be part of a biosensor or a neural interface system. Many such biocompatible electrodes 1 may be incorporated into a multi well plate. Such multi well plates may be used in HTS for example. FIG. 11 shows an example structure of a biosensor. A chamber 8 is defined in this example by a glass ring 20 around an array 21 of electrodes 2. There are electrical connections 22 between the array 22 and a printed circuit board 23.

In use, in a system containing a biocompatible electrode 1, conductance occurs through the base of pores, for example, through aluminium 10 or noble metal 15, and possibly additionally through a barrier layer 12, as discussed above, for recording with the electrode 1 and vice versa for stimulation with the electrode 1. This enables, for example, recorded potential to be sensed at a device such as a complementary metal oxide semiconductor (CMOS) transistor gate. For example, when recording action potential of neuronal cells, with, for example, the relevant medium in the chamber 8, a neuron-alumina junction is formed, which forms a wet electrode below the cell membrane. There may be, for example, a conductive path through the low impedance alumina pores filled with physiological medium, through the impedance at the pore base and to a high impedance transistor gate input.

FIG. 12 shows a neuronal cell 24 positioned above an electrode layer 2 of an electrode 1. The electrode 1 is in place within a package having a chamber 8 containing the cells 24 in a medium and is connected to circuitry 25. As shown in FIG. 12, ions 26 move in the vicinity of the electrode 1 and create an electric field or voltage which is recorded by the electrode 1.

FIG. 13 shows a further example of a system comprising biocompatible electrodes, which may be used as a biosensor. FIG. 13a shows an IC chip having a multi electrode array and a culture chamber 8 in place. FIG. 13b shows a magnified portion of the electrode array in FIG. 13a prior to anodisation. FIG. 13c shows a magnified single electrode pad from FIG. 13b prior to anodisation (tilted). FIG. 13d shows this pad after anodisation.

FIG. 14 shows steps in an example manufacturing process for a biocompatible electrode 1. The starting point 100 of the manufacturing process is a completed IC, such as a CMOS IC, manufactured by any suitable known method, using a valve metal or alloy thereof for its top layer 17 of metallisation. In the examples discussed below, a top layer 17 of aluminium will be referred to.

A simplified cross-section of an example initial CMOS IC metallisation is shown diagrammatically in FIG. 15. In this example, upon a silicon substrate 3, one or more metal layers 17 are patterned. The metal layers 17 are insulated by interlayer dielectrics 4. Windows patterned in the passivation 7 define electrode areas. This is achieved by the same backend step as for bond pads 6a and requires no extra processing. The top metal layer 17 in this example will be referred to as an aluminium layer 18.

FIG. 16 is an enlarged diagram of the boxed area marked c on FIG. 15. In this example the IC has been manufactured so that the there is no barrier layer between the aluminium layer and the insulating layer 4. If it is desired to have a barrier layer 12 in the completed electrode, as mentioned above and shown in FIG. 4, an appropriate completed IC having a barrier layer 12 may be used as a starting point. A barrier layer 12 may be used to avoid the problem of contact spiking, as understood by the skilled person.

An anti-reflective coating 19 may be incorporated above the aluminium layer 17, as shown in FIG. 16, in which case this is removed from electrode 1 and pad 6a areas during the passivation etch in a known manner. This may be desired to avoid lithography problems when manufacturing smaller geometries (for example on fabrication processes of <1.0 μm, that is processes where the smallest feature definable using photolithography is 1.0 μm). The anti-reflective coating stops reflections from the shiny metal surface that would otherwise cause the light during the exposure to fall in the wrong places of the IC.

As shown in FIG. 17, the IC is then assembled 110 to enable the surface 5 of the electrode layers 2 to be exposed to an electrolyte. As discussed above, the surface 5 of electrode layers 2 of the IC in the completed electrode 1 should be open to enable an interface to cells of interest present in a cell culture medium (floating or adhered). The bond pads 6a and bond wires 6b must be insulated from the electrolyte. A chamber 8 may be provided both to hold the electrolyte required for anodisation of the electrode 1 and to hold culture medium for use of the electrode 1 in in-vitro applications. (See FIG. 1.) For example, the IC may be moulded into the base of a custom-moulded multi-well plate. In this case, anodising electrolyte may be placed in each of the wells.

Prior to anodisation, as shown in FIG. 16, the aluminium may optionally be partially etched back 120 to allow for subsequent height increase during anodisation. This height increase is due to a Pilling-Bedworth ratio of 1.28 for aluminium whereby the thickness of the resultant alumina is greater than that of the consumed aluminium. The amount of etching may depend on the thickness of aluminium that is to be anodised and the stress induced in the passivation layer 7, as understood by the skilled person. This step is, however, not essential for satisfactory biocompatible electrode operation.

Anodisation is performed 130 using an appropriate electrolyte (e.g. 4 wt % phosphoric acid) and by connecting the electrode layers 5 to the anodisation bias, either through active CMOS transistor circuits (not shown) or via direct connection (not shown) between each electrode pad and package pins. The cathode is formed by electrical connection (not shown) into the electrolyte. The anodisation creates the porous layer 9 as shown in FIGS. 3 to 7. Anodisation proceeds by consuming the aluminium layer 17, which may be, for example, about 1 μm thick. This conversion of aluminium to alumina eliminates the primary source of corrosion in the finished electrode 1.

The alumina layer 9 shown in FIG. 3 has a structure which is a result of anodisation being terminated after a specified time. This may leave a thinned aluminium layer 10 below the porous alumina 9 that will continue to act as an electrical connection to/from from the electrode 1.

An alternative is to allow anodisation to cease spontaneously when the entire aluminium layer is consumed (result not shown). The ceasing of the anodisation may be detected by a reduction in anodising current. This leaves only the alumina barrier oxide 13.

Between these two methods lies a critical point where the aluminium has been consumed below some pores but small areas of aluminium 14 remain below others, as shown in FIG. 4. This may be detected electrically where the steady-state anodisation current begins to fall. Anodisation may be terminated at this point to provide good electrical continuity to/from the electrode 1 via the remaining thinned aluminium layer 10. This minimises the volume of aluminium, thereby minimising the corrosion risk, whilst simultaneously maintaining good electrical performance.

Any pores that would otherwise fail to conduct through a thick barrier oxide 13 or lack of conducting aluminium 10 below may subsequently be connected electrically via deposited metal 15 across the top of all pores, as discussed below. Where anodisation has consumed all aluminium down to an underlying barrier layer 13, either no thinning may be required to allow conduction due to defects already present in the deformed barrier oxide or the layer 13 may be thinned by a pore-widening etch 140.

Similarly, where anodising is performed at high voltages (above approximately 30V) and terminated prior to consuming the full thickness of aluminium 18, an insulating oxide layer 11 will remain at the base of each pore, as shown in FIG. 3. This may be reduced by either stepping down the voltage towards completion of anodisation or by thinning using a pore-widening etch 140 as shown in FIG. 5. Alternatively the oxide 11 may be doped 150 with a noble metal, as shown in FIG. 6, to increase the oxide's conductivity, which will occur during the subsequent electrodeposition. This is discussed further below.

The dimensions of the pores may be varied to suit the application. Inter-pore spacings between 10 nm and 500 nm may be obtained, for example, or more particularly between 25 nm and 350 nm. Inter-pore spacing is determined by the anodising voltage. For example, 25 nm and 350 nm spacings may be obtained from 10V and 140V respectively. Pore spacing and width may influence the ability of cells to adhere to the electrode surface of the electrodes 1 shown in FIGS. 4, 5A, B, 6B, which may affect the desired pore spacing. Small pore pitches may be desired because this enables only low voltages (e.g. 10V) to be necessary and therefore the voltage could be supplied via the CMOS circuitry itself, if required.

Additional variation of pore size may be controlled by introducing polyethylene glycol (PEG) into the electrolyte (e.g. 10-50 wt %), by reducing the electrolyte aqueous concentrate (e.g. by reducing phosphoric acid concentration from 4% to between 0.5 and 2%) and by controlling temperature.

Pore diameter may also be increased using a pore-widening etch 140, which has been used in the examples shown in FIG. 5. This may be the same etch used as described above to thin a remaining oxide layer 11, 13. The same electrolyte may be used as for anodisation (for example 4 wt % phosphoric acid). By controlling of these parameters either tall narrow pores (FIG. 5A) or short wide pores (FIG. 5B) may be formed, for example.

The electrode 1 may then be coated 150 with a noble metal, as shown in the examples in FIG. 6 having a coating 15. If a coating is applied, this is may be by means of electrodeposition, as this may be advantageously be performed using a similar apparatus and IC configuration as the anodisation. For example, a ductile platinum layer may be obtained by deposition using dinitro-sulphato (DNS) platinum or P-salt baths.

Optionally, the noble metal coating may be additionally covered/processed to improve its performance as shown in FIG. 7 showing the additional layer 16. For example, an additional layer of ‘Platinum Black’ (‘platinised platinum’) may be deposited by using chloroplatinic acid (CPA), to further improve conductivity of the electrode/medium interface. This may again be performed using the same IC configuration as anodisation. Other materials such as nanoporous gold may be deposited to serve a similar purpose.

The electrode design eliminates corrosion of IC metallisation in physiological mediums such as culture mediums and buffers used for electrophysiology and extracellular fluid surrounding an electrode 1 used in an implantable medical device.

The electrode is low impedance and enhances signal transfer between electrode and cell.

IC technology has the flexibility of on-chip signal processing, data storage and data transmission via parallel, serial or wireless communications. In HTS applications these flexible methods allow simple transfer of data to the plate edge or even off plate. The use of IC technology is therefore scalable to large volume applications such as an electrode for drug discovery, where large numbers of compounds need to be screened with high throughput. Examples of high throughput screening where this is beneficial include screening of compounds against ion channels expressed by cells and toxicology screening.

The electrode enables integration with other necessary electronic components, thus being suitable for neural interface systems and other implant products.

For biosensors as discussed above, multi-chip modules may be avoided by integrating the electrode and electronics on one substrate.

The manufacturing technique enables the creation of reliable electrodes without the need for specialist photolithography facilities. As discussed above, this is by means of retro-fitting a porous valve metal oxide, such as alumina, electrode into a completed IC, such as a CMOS IC, wherein the anodic layer growth and underlying aluminium thickness may be controlled. Complex photolithography is avoided by using ‘self patterning’ of porous alumina and if an electrodeposited noble metal 15 is used it may be limited to electrode areas (i.e. avoiding bond pads) by processing after packaging.

If a multi-use chamber 8 is assembled above the IC for containment of etchant/anodising electrolyte and subsequent neuronal cell culture, this simplifies the manufacturing process.

The anodisation, optional pore-widening etch and the optional barrier oxide thinning may all be performed using the same phosphoric acid electrolyte (and also the optional pre-anodisation etch if this is performed). The steps are distinguishable by the voltage and the temperature. For example, the pre-anodisation etch is performed with no electrical bias and at higher temperature than the anodisation. This processing technique minimises manufacturing cost, which contributes to the suitability of the electrode 1 for low-cost applications.

The same culture chamber and electrolyte bath electrode may be used in the porous alumina formation steps and the electrodeposition steps. This simplifies the manufacturing process.

The bath electrode (or ‘reference electrode’) may be the same as the cathode used for anodisation or alternatively the bath electrode may be incorporated on the IC itself, using the same manufacturing steps as for recording/stimulation biocompatible electrodes 1, except that in use the reference electrode is connected to the required bath potential (usually ground) rather than, for example, an amplifier/driver. If such an on-chip reference electrode is to be used for the anodisation manufacturing step it must also be anodised separately as it cannot be simultaneously used as the cathode and at the same time undergo anodisation.

The substrate 3 and optional insulating layer 4 of the electrode 1 may be parts of any suitable known IC with the electrode layer 2 being an alteration of a known IC metallization layer comprising aluminium or its alloys, such as Al—Si, Al—Cu, Al—Si—Cu, Al—Ti. Alternatively, any other valve metal such as tungsten (W), titanium (Ti), tantalum (Ta), hafnium (Hf), niobium (Nb), zirconium (Zr), or alloys thereof may be used. These metals are capable of producing porous oxide layers by anodisation. Anywhere in this disclosure where aluminium and alumina is discussed, these may be substituted by another valve metal and valve metal oxide respectively.

There may be further metallisation layers 17 and insulating layers 4 present, as is standard for CMOS ICs, as shown in FIG. 12. There may be a via directly below the electrode layer 2, that is, a bridging connection between one metallisation layer and another. In this case, in the initial IC before processing, instead of a dielectric 4 directly below the top metallisation layer 17, there is a via below the top metallisation stack 17. The precise nature of the via may vary, as known by the skilled person, but will always comprise some form of conductor. Further, the via itself may comprise either a single layer, for example of tungsten or polysilicon, or several layers, for example a barrier layer of Ti, Ta, TaN, Ta—SiN followed by copper. The via may also be a metal stack, for example of Ti/Al/TiN, that is similar to the layer combination of anti reflective coating 19/top metallisation layer 17/barrier layer 12 before removal of the ARC 19 and processing of the top metallisation layer to become the electrode layer 2.

As mentioned above, there may be no insulation layer 4, with the layout design of the electrode 1 such that the top layer 17 of metallisation of the originating IC contacting the substrate (which may be silicon for example), for example if the IC has only one metallisation layer 17.

Any suitable IC technology may be used, and any suitable completed conventional IC may be used as the starting point of the manufacturing process. For example, as an alternative to CMOS mentioned above, n-type metal oxide semiconductor field effect transistor technology (NMOS) may be used.

The electrode package assembly may comprise any suitable known package. For example, it may be a plastic package with a moulded open-cavity (e.g. ‘partial encapsulation’ by Quik-Pak, U.S.); a ceramic leaded or leadless carrier with an open cavity and bond wires insulated using resin; or the IC can be moulded into the base of a custom-moulded multi-well plate, to give some examples. The package may have as a chamber 8 any suitable vessel that in applications where culture medium is held, preferably holds electrolyte during manufacture and acts as the same vessel that then holds culture medium during use.

As well as possible use of a plastic package, bond wires 6b, a culture chamber 8 and packaging into the base of a multiwell plate, an IC could be incorporated into many other forms of packaging as known by the skilled person. For example, instead of bond wires, ‘flip-chip’ technology may be used, which may be particularly beneficial in a multiwell plate design.

Electrical connection may be made in any suitable manner, depending on the specific electrode 1 design. If connection is via, for example, an alumina layer 9, the impedance at the base of the pores must be sufficiently low to allow the connection. For example, any remaining aluminium 10, 14 or barrier layer 12 may allow electrical connection via this route. As discussed above, thinning of pores may enable electrical connection in this manner and connection via a noble metal coating 15 is a further possibility.

Any suitable noble metal coating 15 and further coating 16 may be used.

The biocompatible electrode 1 may be used in screening any suitable adherent cells, including both stimulating and recording such cells. Cells may be cultured directly in the chamber 8, directly in contact with the electrode 1. Cells usually start as spherical and mobile, then adhere to the chip surface and flatten on the electrode 1 after some time. This process may start within minutes but full adhesion and best recordings may require 1+ days in vitro. Alternatively, cells may be introduced at the testing/sensing/recording stage.

Examples of suitable cell types include cardiomyocytes, neurons and skeletal muscle cells. Another possibility may include a subset of oligodendrocyte precursor glia. Both animal and human continuous cell lines that are electrically excitable may be suitable, such as NG108-15, B50, LA-N-5 and PC12.

Further, any suitable method that brings cells into contact with the electrode 1 may be performed, such as stimulation or recording of tissue slices. The biocompatible electrode 1 may be used in any application where an electrode is used to stimulate or record from cells, including measurement of alteration in electrical activity when cells are stimulated for example with an agonist.

An array 21 of biocompatible electrodes 1, which may be formed from a single chip, may be linked to, for example, means for obtaining and displaying a spatial readout of cell activity. If multiple electrodes are fitted to wells, this system may be linked to a means for obtaining and displaying a spatial readout of cell activity across the wells. Spatial activity within wells may also be measured. For example, multiple electrodes within one well may be used to acquire information on the number of neurons simultaneously excited within that well, and this well may also be compared with other wells.

Biocompatible electrodes 1 may be connected to an output device, such as a computer, that may manipulate, for example, acquired stimulation/response data, for example by displaying cell response data as an array of information on a PC screen. Another alternative is for the ‘output device’ to comprise partly of logic within the IC itself. For example, IC logic surrounding an electrode array may process cell response data, such as action potential magnitude, frequency, shape, and transmit only a summary, such as pass/fail versus a programmed limit, for example to a PC sited away from the IC.

The biocompatible electrode 1 may be used to record/stimulate any excitable cell and/or cells expressing ion channels. Any excitable adherent cells, that is, cells capable of adhering to the electrode may be applicable. For example, cells that fire action potential may be recorded from. Compounds that directly modify action potential and receptors that ultimately alter cell excitability may be screened for. Compounds capable of modulating the activity of ion channels if the ion channel is involved in action potential generation or action potential modulation may be screened for.

In general, biocompatible electrodes 1 may be configured to manipulate cells. Biocompatible electrodes 1 may be used to set up an electric field that is able to cause movement of particles, usually cells. The particles move in response to the electrical signal. This is the phenomenon of electrophoresis. More specifically, the electrodes 1 may be used to move cells to a specific location, such as above a recording/stimulation electrode 1, often using the specific form of electrophoresis termed ‘negative dielectrophoresis’ (“Negative-DEP” or “N-DEP”). As cells respond differently to electric fields and migrate towards positive or negative fields, this may be used, for example, to sort cancerous cells (in which case this may also constitute diagnosis or testing for the presence of cancerous cells) or other diseased cells, or to separate different cell types, for example for regenerative medicine purposes where it may be desired to pattern different cell types to mimic tissues.

The electrode 1 may be used to measure capacitance, often termed Electric Cell-Substrate Impedance Sensing (ECIS). For example, ECIS may be used to differentiate between cell types and between normal and diseased cells.

The electrode 1 may be used for other applications, not limited to cell based applications and including non-recording applications, such as ‘cell sorting’ or other diagnosis applications, by applying electrodes 1 to moving cells or other biological particles such as proteins.

The electrode 1 may also be used in toxicology applications, for example in screening hERG channels. High throughput screening of cells may be performed wherein electrophysiological response is an indicator of toxicity. For example, compounds may be screened to determine whether they cause modification to the action potential in cardiomyocytes. From this it may be determined whether they will affect calcium signalling in the heart and cause, for example, cardiotoxicity.

What is claimed is:

1. A biocompatible electrode formed from an integrated circuit, the electrode comprising:
a semiconductor substrate; and
an electrode layer at least partially comprising porous valve metal oxide, wherein the electrode layer further comprises a noble metal coating arranged to coat at least some of the porous valve metal oxide.

2. The electrode according to claim 1, wherein the electrode layer further comprises one of a valve metal and a valve metal alloy at least partially in contact with at least some of the porous valve metal oxide.

3. The electrode according to claim 2, further comprising an electrical connection to the porous valve metal oxide via the one of the valve metal and a valve metal alloy.

4. (canceled)

5. The electrode according to claim 1, further comprising an electrical connection to the porous valve metal oxide via the noble metal coating.

6. The electrode according to claim 1, farther comprising a second coating arranged to coat at least some of the noble metal coating.

7. The electrode according to claim 1, farther comprising an insulating layer or via to one or more metal layers between the substrate and electrode layer.

8. The electrode according to claim 1, farther comprising a barrier layer in between the insulating or substrate layers or via and the electrode layer.

9. The according to claim 1, wherein the electrode is comprised by a complementary metal oxide semiconductor integrated circuit with the electrode layer being formed from a metallization layer of the integrated circuit comprising at least partially anodised valve metal.

10. The electrode according to claim 1, wherein the valve metal is one of aluminium (Al), tungsten (W), titanium (Ti), tantalum (Ta), hafnium (Hf), niobium (Nb) and zirconium (Zr).

11. The A multiple electrode array comprising an electrode according to claim 1.

12. A system comprising a multiple electrode array according to claim 11 fitted to a single or multiple well plate.

13. A biosensor comprising an electrode, multiple electrode array or system according to claim 1.

14. An electrode, multiple electrode array, system or biosensor substantially as described herein with reference to the accompanying drawings.

15. A method of manufacturing a biocompatible electrode, the method comprising the steps of:
exposing a metallization layer of an integrated circuit to an electrolyte, the metallization layer comprising one of valve metal and a valve metal alloy; and
anodising at least some of the metallization layer with the electrolyte to obtain an electrode layer comprising porous valve metal oxide.

16. The method according to claim 15, further comprising controlling at least one of temperature and voltage during the anodising step to control at least one of volume and pore size of the resultant valve metal oxide.

17. The method according to claim 15, further comprising controlling polyethylene glycol (PEG) concentration and acid concentration components of the electrolyte to control at least one of volume and pore size of the resultant valve metal oxide.

18. The method according to any of claim 15, further comprising the step of etching the valve metal oxide subsequent to the anodising step.

19. The method according to claim 15, further comprising the step of coating at least some of the electrode layer.

20. The method according to claim 19, wherein the coating step comprises electrodeposition.

21. The method according to claim 19, wherein the coating step comprises coating at least some of the valve metal oxide with a noble metal coating.

22. The method according to any of claim 19, further comprising processing the coated electrode layer.

23. The method according to claim 19, further comprising providing a second coating on at least some of the coated electrode layer.

24. The method according to claim 15, wherein the electrolyte and etchant are the same.

25. The method according to claim 15, wherein the integrated circuit is a complementary metal oxide semiconductor integrated circuit.

26. The method according to claim 15, wherein the valve metal is one of aluminium (Al), tungsten (W), titanium (Ti), tantalum (Ta), hafnium (Hf), niobium (Nb) and zirconium (Zr).

27. (canceled)

28. The method of separating particles comprising separating the particles by means of an electrode according to claim 1, wherein the electrode is arranged such that the particles are adherent thereto.

29. The method according to claim 28, wherein the particles comprise at least one of cells and proteins.

30. The method according to claim 28, wherein the method comprises Electric Cell-Substrate Impedance Sensing (ECIS) or dielectrophoresis.

31. The method according to claim 28, wherein the method further comprises diagnosing a disease.
